(19) United States
(12) Patent Application Publication
(10) Pub. No.: US 2023/0031422 A1
(43) Pub. Date: Feb. 2, 2023

(54) METHOD OF MANUFACTURING SUBSTRATES FOR SEMICONDUCTOR DEVICES, CORRESPONDING SUBSTRATE AND SEMICONDUCTOR DEVICE

(71) Applicant: STMicroelectronics S.r.l., Agrate Brianza (MB) (IT)

(72) Inventor: Mauro MAZZOLA, Calvenzano (BERGAMO) (IT)

(73) Assignee: STMicroelectronics S.r.l., Agrate Brianza (MB) (IT)

(21) Appl. No.: 17/871,203

(22) Filed: Jul. 22, 2022

(30) Foreign Application Priority Data
Jul. 28, 2021 (IT) 102021000020114

(51) Int. Cl. H01L 21/48; H01L 23/495

(52) U.S. Cl. CPC H01L 21/4839; H01L 23/49503; H01L 23/49558

(57) ABSTRACT

A pre-molded substrate includes a sculptured, electrically conductive laminar structure having spaces therein. The laminar structure includes a die pad having a first die pad surface configured to mount a semiconductor chip. A pre-mold material molded onto the laminar structure penetrates into the spaces and provides a laminar pre-molded substrate with the first die pad surface left exposed. The peripheral edge of the die pad includes an alternation of first and second anchoring formations to the pre-mold material. The first anchoring formations counter first detachment forces inducing displacement of the die pad with respect to the pre-mold material in a first direction from the second die pad surface to the first die pad surface. The second anchoring formations counter second detachment forces inducing displacement of the die pad with respect to the pre-mold material in a second direction from the first die pad surface to the second die pad surface.

### PRIORITY CLAIM

This application claims the priority benefit of Italian Application for Patent No. 102021000020114, filed on Jul. 28, 2021, the content of which is hereby incorporated by reference in its entirety to the maximum extent allowable by law.

### TECHNICAL FIELD

The description relates to semiconductor devices.

One or more embodiments can be applied to semiconductor power devices for the automotive sector, for instance.

### BACKGROUND

In substrates such as pre-molded leadframes, adequate adhesion between the sculptured, electrically conductive structure of the leadframe (copper, for instance) and the pre-mold resin (an epoxy resin, for instance) molded thereon should desirably absorb stresses generated if the pre-molded leadframe is pressed or bent.

Particularly, pads in pre-molded leadframes should desirably resist pressing forces (as developed, e.g., during ribbon ultrasonic wedge bonding) as well as pulling forces (as developed, e.g., during ribbon pulling for second bond, or as a result thermo-mechanical stress under operation).

It is noted that, while advantageous for other purposes, slot-like anchoring structures provide limited pulling resistance while taking a non-negligible pad area.

There is a need in the art to deal with the issues as discussed in the foregoing.

### SUMMARY

One or more embodiments relate to a method.

One or more embodiments relate to a corresponding substrate (leadframe) for semiconductor devices.

One or more embodiments relate to a semiconductor device.

One or more embodiments provide a die pad design for a pre-molded leadframe (formed through standard half-etch before pre-molding, by a leadframe supplier, for instance) comprising an alternation of ‘fingernail-like’ anchoring structures on the top and bottom sides of the die pad.

### BRIEF DESCRIPTION OF THE DRAWINGS

One or more embodiments will now be described, by way of example only, with reference to the annexed figures, wherein:

FIG. 1 is exemplary of a conventional substrate such as a pre-molded leadframe and of forces that may be applied to such a leadframe;

FIG. 2 is exemplary of a similar substrate provided with slot-like anchoring structures;

FIGS. 3A and 3B are cross-sectional along line II-II of FIG. 2 showing how a substrate as illustrated in FIG. 2 can resist opposite forces applied thereto;

FIG. 4 is a perspective view of a part of the structure of a substrate such as a pre-molded leadframe according to embodiments of the present description;

FIG. 5 is a cross-sectional view along lines V-V in FIG. 4; and

FIGS. 6 and 7 are view substantially corresponding to the view of FIG. 5 showing possible variants of embodiments of the present description.

### DETAILED DESCRIPTION

Corresponding numerals and symbols in the different figures generally refer to corresponding parts unless otherwise indicated.

The figures are drawn to clearly illustrate the relevant aspects of the embodiments and are not necessarily drawn to scale.

The edges of features drawn in the figures do not necessarily indicate the termination of the extent of the feature.

In the ensuing description, various specific details are illustrated in order to provide an in-depth understanding of various examples of embodiments according to the description. The embodiments may be obtained without one or more of the specific details, or with other methods, components, materials, etc. In other cases, known structures, materials, or operations are not illustrated or described in detail so that various aspects of the embodiments will not be obscured.

Reference to “an embodiment” or “one embodiment” in the framework of the present description is intended to indicate that a particular configuration, structure, or characteristic described in relation to the embodiment is comprised in at least one embodiment. Hence, phrases such as “in an embodiment”, “in one embodiment”, or the like, that may be present in various points of the present description do not necessarily refer exactly to one and the same embodiment. Furthermore, particular configurations, structures, or characteristics may be combined in any adequate way in one or more embodiments.

The headings/references used herein are provided merely for convenience and hence do not define the extent of protection or the scope of the embodiments.

Semiconductor devices may comprise one or more semiconductor chips or dice arranged (attached) on substrates such as leadframes.

Plastic packages are commonly used for semiconductor devices. Such packages may include a leadframe providing a base substrate comprising electrically conductive material such as copper, sized and shaped to accommodate semiconductor chips or dice and providing pad connections (leads) for these chips or dice.

The designation “leadframe” (or “lead frame”) is currently used (see, for instance the USPC Consolidated Glossary of the United States Patent and Trademark Office) to indicate a metal frame that provides support for an integrated circuit chip or die as well as electrical leads to interconnect the integrated circuit in the die or chip to other electrical components or contacts.

Leadframes are conventionally created using technologies such as a photo-etching technology. With this technology, metal (e.g., copper) material in the form of a foil or tape is etched on the top and bottom sides to create various pads and leads.

Substrates such as leadframes are advantageously provided in a pre-molded version wherein an insulating resin (an epoxy resin, for instance) fills the empty spaces between the die pads and leads.

A pre-molded leadframe is a thus a laminar substrate that is substantially flat with the pre-mold material (resin) filling the spaces in the electrically conductive structure (metal material such as copper, for instance) of the leadframe, that has been bestowed a sculptured appearance including empty spaces during forming, by etching, for instance.

The total thickness of the pre-mold leadframe is the same thickness of the sculptured electrically conductive structure.

During the assembly process of semiconductor devices using a pre-molded leadframe, a pre-molded leadframe can be exposed to repeated stress.

Particularly, pads in pre-molded leadframes are exposed to pressing forces (as developed, e.g., during ribbon ultrasonic wedge bonding) as well as to pulling forces (as developed, e.g., during ribbon pulling for second bond, or as a result of thermo-mechanical stress under operation).

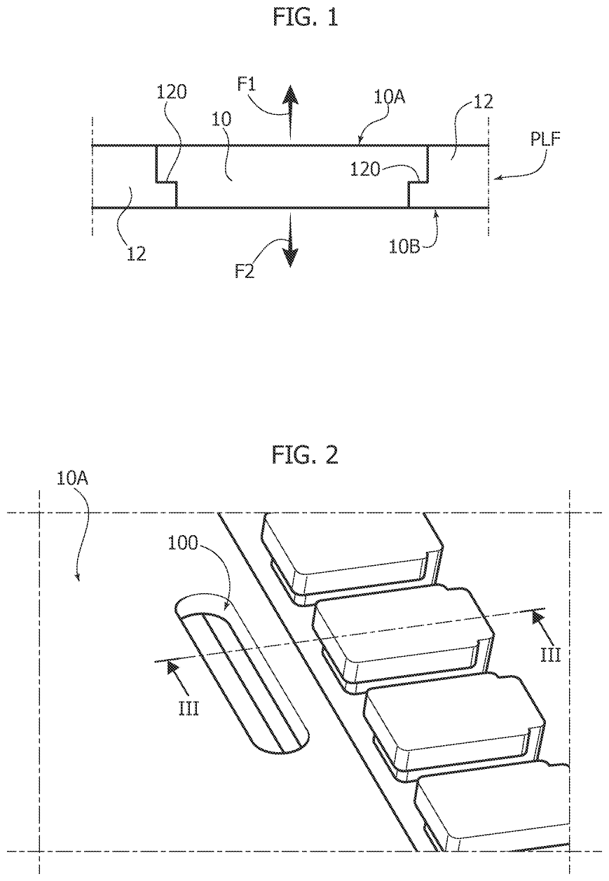

FIG. 1 is a cross-sectional view of a portion of a pre-molded leadframe illustrated as comprising, in general, electrically conductive (metal, e.g., copper) portions 10 included in a sculptured, electrically conductive structure of the leadframe (not visible in its entirety), having spaces filled by the pre-mold material (resin) 12.

A pre-molded leadframe PLF as illustrated in FIG. 1 has opposite first and second die pad surfaces 10A and 10B, with the first surfaces 10A configured to have at least one semiconductor chip mounted thereon.

FIG. 1 is thus exemplary of an approach wherein a sculptured, electrically conductive laminar structure is provided having spaces therein, the laminar structure including one or more die pads 10 having a first die pad surface 10A configured to have at least one semiconductor chip mounted thereon as well as a second die pad surface 10B opposite the first die pad surface 10A.

FIG. 1 is likewise exemplary of an approach wherein pre-mold material 12 is molded onto the laminar structure 10. The pre-mold material 12 penetrates into the spaces formed (e.g., etched) in the sculptured, electrically conductive laminar structure and provides a laminar pre-molded substrate PLF 10, 12 including one or more die pads left exposed by the pre-mold material 12 at the first surface 10A with the periphery of the die pad or pads 10 bordering on the pre-mold material 12 molded onto the laminar structure.

As illustrated in FIG. 1, the sculpturing bestowed on the electrically conductive (metal, e.g., copper) portions 10 of the (pre-molded) leadframe is beneficial in keeping all the leadframe parts (leads and die pads) together in a robust structure to facilitate the subsequent process steps.

These steps may include, for instance—after attaching one or more chips or dice on the die pad or pads in the leadframe 10, 12 and the chips or dice being electrically bonded to the leads in the leadframe (not explicitly visible in FIG. 1)—a molding resin being molded to provide an insulating encapsulation of a final device.

FIG. 1 is exemplary of a leadframe for, e.g., a Quad-Flat No-leads (QFN) device where the sculptured, electrically conductive structure of the leadframe is half etched, that is, a part of copper material is removed, e.g., at the periphery of die pad so that (as visible in FIG. 1) the die pad is larger at the front or top surface 10A of the leadframe than at the back or bottom surface 10B of the leadframe.

Half etching can be performed in any manner known to those of skill in the art.

Also, while “half” etching is currently referred to for simplicity, the part of copper material removed does not necessarily correspond to half the thickness of the metal structure of the leadframe.

It is noted that the description above also applies—mutatis mutandis—to the embodiments discussed in the following, e.g., in connection with FIGS. 4 to 7. Such a detailed description will not be repeated for brevity.

The die pad being larger at the front or top surface 10A than at the back or bottom surface 10B as illustrated in FIG. 1 increases the molding adhesion around the leadframe parts. This is due to a step-like interface formed between the conductive (metal, e.g., copper) portions 10 of the leadframe and the pre-mold material (resin) 12 molded thereon.

After the pre-mold material is solidified (e.g., by thermosetting, as otherwise conventional in the art) this design results in increased resistance to detachment (delamination) between the conductive portions 10 of the leadframe and the non-conductive pre-mold material 12 molded thereon as possibly induced by “pulling” forces F1 (namely forces urging the metal part 10 shown in FIG. 1 in the direction from the back or bottom surface 10B towards the front or top surface 10A) and by “pushing” or “pressing” forces F2 (namely forces urging the metal part 10 shown in FIG. 1 in the direction from the front or top surface 10A towards the back or bottom surface 10B).

Such a step-like interface includes undercuts as indicated at 120 where the periphery of the conductive portion 10 of the leadframe abuts against the pre-mold material (resin) 12. This provides a form coupling such that the resistance to “pushing” forces F2 (directed downwards in FIG. 1) is inevitably (much) higher than the resistance to “pulling” forces F1 (directed upwards in FIG. 1).

Forces applied to a pre-molded leadframe such as 10, 12 in FIG. 1 during the assembly flow of a semiconductor device include both pressing forces such as, e.g., pressing forces applied during ribbon bonding by a bonding tool together with ultrasonic vibrations and pulling forces, e.g., when a ribbon is pulled or cut by moving or opening a bonding cutting tool.

An arrangement as illustrated in FIG. 1, with the undercuts 120 contrasting mainly the pressing forces (e.g., F2) and exhibiting poor adhesion resistance to pulling forces (e.g., F1) cannot be regarded as satisfactory for a variety of practical applications.

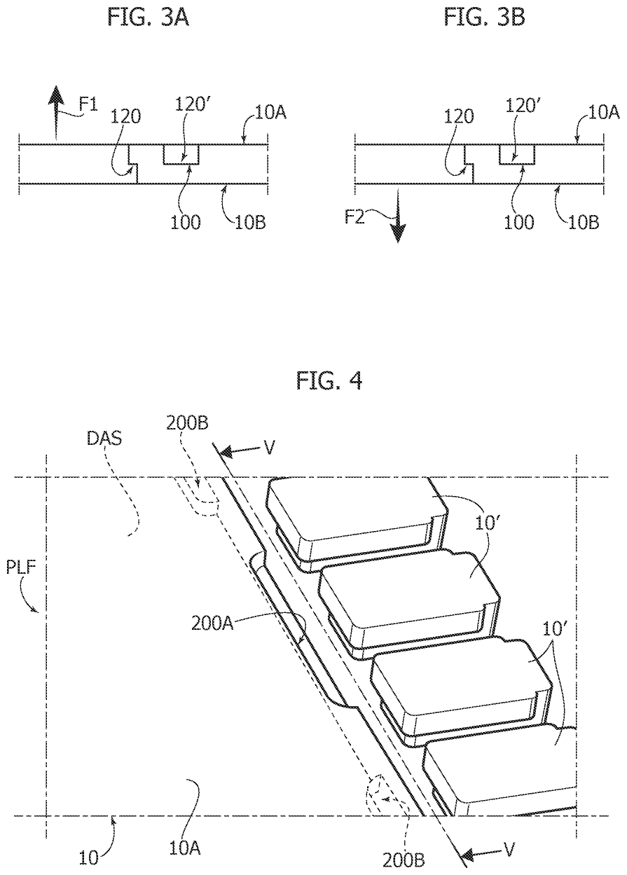

FIG. 2 and FIGS. 3A and 3B illustrate a solution as disclosed in United States Patent Application Publication No. 2021/0193591 (to which EP 3 840 040 A1 corresponds) assigned to the same Assignee of the present application.

The leadframe of United States Patent Application Publication No. 2021/193591 A1 comprises a die pad portion having a first planar die-mounting surface 10A and a second planar surface 10B opposed the first surface 10A.

As visible in FIG. 2 (where the conductive structure 10 of the leadframe is shown prior to molding the pre-mold material 12) the die pad surfaces 10A and 10B have facing peripheral rims jointly defining a peripheral outline of the die pad. At least one cavity 100 is provided extending through the die pad from the first planar surface 10A to the second planar surface 10B to define an anchoring portion of the die pad positioned between said at least one cavity and the peripheral outline.

A first etched part extends into the first planar die-mounting surface 10A to a first depth less than a thickness of the die pad and a second etched part extends into the second planar surface to a second depth less than the thickness of the die pad. The first etched part defines a step surface within the cavity 100 that extends parallel to the first planar die-mounting surface 10A and the second etched part defines a thickness of the anchoring portion which is less than the thickness of the die pad.

FIGS. 3A and 3B (where the pre-mold material 12 is visible, filling the spaces in the sculptured, electrically conductive structure 10 of the leadframe) show that such an arrangement may lead to the formations of undercuts 120, 120′ facing in opposite directions.

These undercuts 120 and 120′ provide a form coupling of the electrically conductive structure 10 of the leadframe and the pre-mold material 12 providing improved resistance also to pulling forces F1 (FIG. 3A) in addition is pushing or pressing forces F2 (FIG. 3B).

Here again, however, the resistance to pushing forces F2 may end up by being higher than the resistance to pulling forces F1, while for certain applications having a resistance to pulling forces F1 equal or possibly higher than the resistance to pushing or pressing forces F2 may be a desirable feature.

In any case, cavities/apertures such as 100 in FIGS. 2, 3A and 3B subtract area that should be desirably left available for die attachment.

In FIGS. 4 to 7, parts or elements like parts or elements already discussed in connection with the previous figures are indicated with like reference symbols, so that a detailed description will not be repeated for brevity.

Examples as presented in FIGS. 4 to 7 comprise, in the place of a half-etched step-like metal-to-resin interface (as illustrated in FIG. 1) or slots (such as 100 in FIG. 2), an alternation or series of (e.g., fingernail-like) cutaway portions 200A, 200B formed along the border (that is, along the peripheral edge) of the die pad 10, advantageously all around the die pad 10. Each cutaway portion is formed by a half-etched slot arranged at (and extending in from) the peripheral edge of the die pad.

These cutaway portions 200A, 200B, that are arranged alternatively (possibly alternately) at the front or top surface 10A and at the back or bottom surface 10B, are filled by the pre-mold resin 12 creating (once the resin is solidified, e.g., via thermosetting) a robust structure of the pre-molded leadframe PLF.

The cutaway portions 200A, 200B may be all equal in shape (e.g., with a same length in the direction of the edges the die pad 10).

The cutaway portions 200A, 200B may be provided equal in number at the front or top surface 10A and at the back or bottom surface 10B, so the resistance and the resin adhesion is balanced in both directions (forces F1 and F2).

The provision of the cutaway portions 200A, 200B does not entail any appreciate reduction of the surface (indicated as DAS in FIG. 4) available for die attachment (and possibly for the provision of associated ribbons or wires) at the front surface 10A of the leadframe.

As visible, e.g., in FIG. 4 the top or front surface of the die pad designated DAS is exempt from any aperture such as the slot 100 in FIG. 2.

It is noted that in the perspective view of FIG. 4 the conductive structure 10 of the leadframe is shown prior to molding the pre-mold material 12, with also some of the leads of the leadframe, indicated 10′, visible on the right-hand side of FIG. 4.

Examples as presented in FIGS. 4 to 7 comprise at and along the peripheral edge of the pad 10 an alternation of first anchoring formations 200A and second anchoring formations 200B that anchor the pad 10 to the pre-mold material 12 thus providing (once the material 12 is solidified, e.g., via thermosetting) a robust structure of the pre-molded leadframe PLF.

The first anchoring formations 200A are configured to counter “pulling” detachment forces, namely forces such as F1 inducing displacement of the die pad 10 with respect to the pre-mold material 12 in a first direction (upwards in the figures) from the second die pad surface 10B to the first die pad surface 10A.

The second anchoring formations 200B are configured to counter “pushing” or “pressing” detachment forces, namely forces such as F2 inducing displacement of the die pad 10 with respect to the pre-mold material 12 in a second direction (downwards in the figures) from the first die pad surface 10A to the second die pad surface 10A.

As illustrated herein, the first anchoring formations 200A are provided at the first die pad surface 10A and the second anchoring formations 200B are provided at the second die pad surface 10B.

While other shapes (e.g., protrusions) are possible, providing the anchoring formations 200A and 200B as cutaway portions of the peripheral edge of the die pad 10 is advantageous in so far as the pre-mold material 12 can penetrate into these cutaway portions at the peripheral edge of the die pad 10 and establish (once solidified) a strong bond keeping together the various portions of the leadframe PLF.

Irrespective of the specific implementation details, a good degree of flexibility exists in providing an alternation of anchoring formations 200A and 200B along the peripheral edge at one or more of the sides of a die pad such as the die pad 10 illustrated herein.

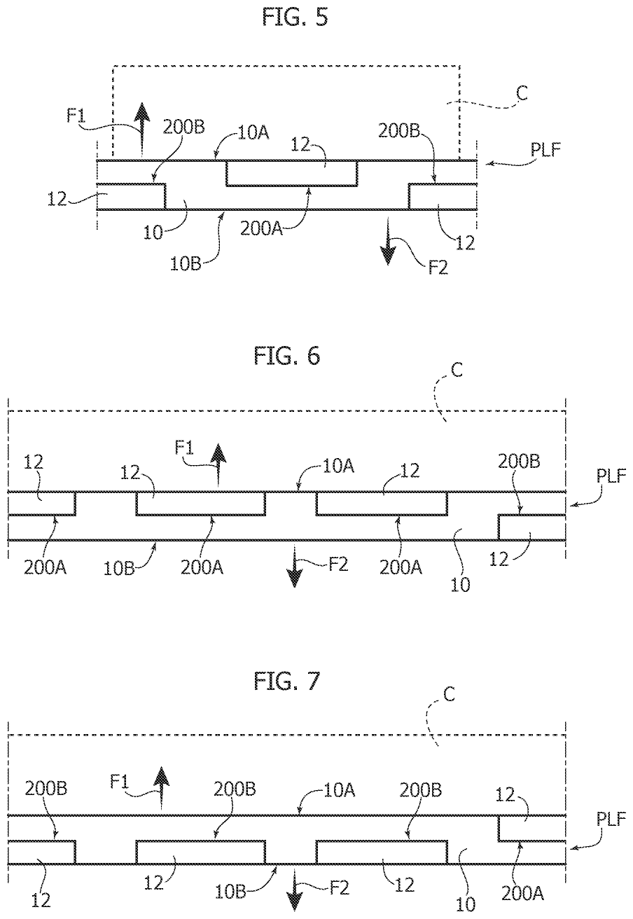

As exemplified in FIG. 5 the alternation of first anchoring formations 200A and second anchoring formations 200B may comprise single first anchoring formations 200A alternating (interleaved) with single second anchoring formations 200B.

That is, the alternation as exemplified in FIG. 5 comprises the sequence of a first formation 200A, a second formation 200B, a first formation 200A, a second formation 200B, and so on.

As exemplified in FIGS. 6 and 7 the alternation of first anchoring formations 200A and second anchoring formations 200B may comprises at least one single first anchoring formation 200A alternating with a plurality of second anchoring formations 200B.

For instance: the alternation as exemplified in FIG. 6 comprises the sequence of three first formations 200A followed by a second formation 200B; and the alternation as exemplified in FIG. 7 comprises the sequence of three second formations 200B followed by a first formation 200A.

While not expressly illustrated for brevity, the alternation may comprise plural first formations 200A interleaved with plural second formation 200B.

For instance (this is just one possible example) the alternation may comprise the sequence of three first formations 200A followed by two second formations 200B, in turn followed by three first formations 200A again followed by two second formations 200B, and so on.

Such interleaving may also comprise different numbers of first and second formations at each iteration.

For instance (again, this is just one possible example) the alternation may comprise the sequence of three first formations 200A followed by two second formations 200B, in turn followed by two first formations 200A followed by three second formations 200B, and so on.

This flexibility may be advantageously relied upon to “adjust” as desired the resistance of the leadframe PLF to pulling forces and pushing or pressing forces.

This may possibly take into account the characteristics of the semiconductor chips or dice intended to be mounted (attached) on the leadframe PLF. In FIGS. 5 to 7 the outline of a semiconductor chip or die C mounted onto the die pad 10 is shown in dashed line.

For instance, providing in the alternation equal numbers of first anchoring formations 200A and second anchoring formations 200B (see, e.g., FIG. 5) facilitates making the laminar pre-molded substrate PLF equally resistant to pulling forces F1 and to pushing or pressing forces F2.

Providing in the alternation first anchoring formations 200A higher in number than the second anchoring formations 200B (see FIG. 6) facilitate making the laminar pre-molded substrate PLF more resistant to pulling forces F1 than to pushing or pressing forces F2.

Providing in the alternation second anchoring formations 200B higher in number than the first anchoring formations 200A (see FIG. 7) facilitate making the laminar pre-molded substrate PLF more resistant to pushing or pressing forces F2 than to pulling forces F1.

Options as exemplified in FIGS. 6 and 7 may be helpful in dealing with semiconductor chips or dice C mounted on the die pad surface 10A left exposed by the pre-mold material 12 that are warped. This may be the case of large and/or thin semiconductor chips or dice C that may exhibit “crying” or “smiling” shapes.

Without prejudice to the underlying principles, the details and embodiments may vary, even significantly, with respect to what has been described in the foregoing, by way of example only, without departing from the extent of protection.

The claims are an integral part of the technical teaching provided herein with reference to the embodiments.

The extent of protection is determined by the annexed claims.

1. A method, comprising:
providing a sculptured electrically conductive laminar structure having spaces therein, the sculptured electrically conductive laminar structure including at least one die pad having a first die pad surface configured to mount a semiconductor chip as well as a second die pad surface opposite the first die pad surface; and
molding pre-mold material to penetrate into said spaces of the sculptured electrically conductive laminar structure and provide a laminar pre-molded substrate including said first die pad surface left exposed by the pre-mold material with the peripheral edge of the at least one die pad bordering on the pre-mold material molded onto the sculptured electrically conductive laminar structure;
wherein providing the sculptured electrically conductive laminar structure comprises providing at the peripheral edge of the at least one die pad an alternation of:
first anchoring formations of the at least one die pad to the pre-mold material, the first anchoring formations configured to counter first detachment forces inducing displacement of the at least one die pad with respect to the pre-mold material in a first direction from the second die pad surface to the first die pad surface; and
second anchoring formations of the at least one die pad to the pre-mold material, the second anchoring formations configured to counter second detachment forces inducing displacement of the at least one die pad with respect to the pre-mold material in a second direction from the first die pad surface to the second die pad surface.

2. The method of claim 1, wherein the first anchoring formations are located at the first die pad surface and the second anchoring formations are located at the second die pad surface.

3. The method of claim 1, wherein each of the first and the second anchoring formations is provided as a cutaway portion of the peripheral edge of the at least one die pad, wherein the pre-mold material molded onto the sculptured electrically conductive laminar structure penetrates into said cutaway portions at the peripheral edge of the at least one die pad.

4. The method of claim 1, wherein said alternation of first anchoring formations and second anchoring formations comprises at least two first anchoring formations alternating with at least two second anchoring formations.

5. The method of claim 1, wherein said alternation of first anchoring formations and second anchoring formations comprises a single first anchoring formation alternating with a single second anchoring formation.

6. The method of claim 1, further comprising providing in said alternation equal numbers of first anchoring formations and second anchoring formations, wherein the laminar pre-molded substrate is equally resistant to said first detachment forces and to said second detachment forces.

7. The method of claim 1, further comprising providing in said alternation first anchoring formations greater in number than said second anchoring formations, wherein the laminar pre-molded substrate is more resistant to said first detachment forces than to said second detachment forces.

8. The method of claim 1, further comprising providing in said alternation second anchoring formations greater in number than said first anchoring formations, wherein the laminar pre-molded substrate is more resistant to said second detachment forces than to said first detachment forces.

9. A substrate, comprising:
a sculptured electrically conductive laminar structure having spaces therein, the sculptured electrically conductive laminar structure including at least one die pad having a first die pad surface configured to mount a semiconductor chip mounted thereon as well as a second die pad surface opposite the first die pad surface; and
pre-mold material molded onto the sculptured electrically conductive laminar structure, wherein the pre-mold material penetrates into said spaces and provides a laminar pre-molded substrate including said first die pad surface left exposed by the pre-mold material with the periphery of the at least one die pad bordering on the pre-mold material molded onto the sculptured electrically conductive laminar structure;
wherein along the peripheral edge of the at least one die pad there is provided an alternation of:
first anchoring formations of the at least one die pad to the pre-mold material, the first anchoring formations configured to counter first detachment forces inducing displacement of the at least one die pad with respect to the pre-mold material in a first direction from the second die pad surface to the first die pad surface; and
second anchoring formations of the at least one die pad to the pre-mold material, the second anchoring formations configured to counter second detachment forces inducing displacement of the at least one die pad with respect to the pre-mold material in a second direction from the first die pad surface to the second die pad surface.

10. The substrate of claim 9, wherein the first anchoring formations are provided at the first die pad surface and wherein the second anchoring formations are provided at the second die pad surface.

11. The substrate of claim 9, wherein each of the first and the second anchoring formations comprises a cutaway portion of the peripheral edge of the at least one die pad, wherein the pre-mold material molded onto the sculptured electrically conductive laminar structure penetrates into said cutaway portions of the peripheral edge of the at least one die pad.

12. The substrate of claim 9, wherein said alternation of first anchoring formations and second anchoring formations comprises at least two first anchoring formations alternating with at least two second anchoring formations.

13. The substrate of claim 9, wherein said alternation of first anchoring formations and second anchoring formations comprises a single first anchoring formations alternating with a single second anchoring formation.

14. The substrate of claim 9, wherein said alternation comprises equal numbers of first anchoring formations and second anchoring formations, wherein the laminar pre-molded substrate is equally resistant to said first detachment forces and to said second detachment forces.

15. The substrate of claim 9, wherein said alternation comprises first anchoring formations greater in number than said second anchoring formations, wherein the laminar pre-molded substrate is more resistant to said first detachment forces than to said second detachment forces.

16. The substrate of claim 9, wherein said alternation comprises second anchoring formations greater in number than said first anchoring formations, wherein the laminar pre-molded substrate is more resistant to said second detachment forces than to said first detachment forces.

17. A semiconductor device, comprising:
a substrate according to claim 9; and
a semiconductor chip mounted on the at least one die pad surface left exposed by the pre-mold material.
